(19) United States
(12) Patent Application Publication
(10) Pub. No.: US 2013/0083930 A1
(43) Pub. Date: Apr. 4, 2013

(54) ELECTRONIC APPARATUS, METHOD OF CORRECTING ACOUSTIC SIGNAL AND STORAGE MEDIUM

(71) Applicant: Chikashi SUGIURA, Hamura-shi (JP)

(72) Inventor: Chikashi SUGIURA, Hamura-shi (JP)

(73) Assignee: KABUSHIKI KAISHA TOSHIBA, Tokyo (JP)

(21) Appl. No.: 13/480,759

(22) Filed: May 25, 2012

(30) Foreign Application Priority Data
Sep. 30, 2011 (JP) 2011-217330

(51) Int. Cl. H04R 29/00; H03G 5/00

(52) U.S. Cl. 381/56

(57) ABSTRACT

According to one embodiment, an electronic apparatus outputs sound in a first frequency band at different sound pressures a first number of times. The electronic apparatus receives a number of hearings of the output sound. The electronic apparatus determines an auditory property of a subject based on the received number of hearings of the output sound. The electronic apparatus corrects an acoustic signal based on the determined auditory property.

### CROSS-REFERENCE TO RELATED APPLICATIONS

This application is based upon and claims the benefit of priority from prior Japanese Patent Application No. 2011-217330, filed Sep. 30, 2011; the entire contents of which are incorporated herein by reference.

### FIELD

Embodiments described herein relate generally to the technique for correcting an acoustic signal according to an auditory property.

### BACKGROUND

Generally, older people have poorer hearing than young people (hereinafter, a person who has normal hearing without deterioration in hearing is referred to as a normal hearer). Specifically, older people have difficulty hearing quiet sounds. This tendency is more noticeable as the frequency of sound increases (the tendency is much more noticeable in a frequency band higher than 8 to 10 kHz, though it varies between individuals).

A hearing aid is a medical apparatus for correcting an acoustic signal (hereinafter, referred to as hearing correction) according to such an auditory property. Hearing correction, which is a process according to the hearing acuity of a user, requires the hearing acuity of the user to be measured in advance. A person with specialized knowledge generally measures hearing acuity with an instrument known as an audiometer by causing a subject to listen to text sound in various frequency bands at intervals of 125, 250, 500, 1000, 2000, 4000, and 8000 Hz to see how low sound pressure the user can hear.

These days, various electric home appliances with the function of outputting an acoustic signal, including a television receiver, a personal computer, a mobile terminal, a tablet terminal, a telephone, an interphone, and a car navigation system, are being used. In recent years, a refrigerator, a microwave oven, a cooking range, and an air conditioner, which have the function of, for example, guiding the operation procedure by voice, have began to be popularized.

Here, suppose hearing correction is applied to a general electric home appliance with the function of outputting such an acoustic signal. In this case, it is unrealistic to measure the hearing acuity of the user of a general home appliance because the measurement is very time-consuming as described above.

### BRIEF DESCRIPTION OF THE DRAWINGS

A general architecture that implements the various features of the embodiments will now be described with reference to the drawings. The drawings and the associated descriptions are provided to illustrate the embodiments and not to limit the scope of the invention.

FIG. 1 is an exemplary diagram showing an external appearance of an electronic apparatus according to a first embodiment.

FIG. 2 is an exemplary diagram showing a system configuration of the electronic apparatus according to the first embodiment.

FIG. 3 is an exemplary graph showing an auditory property pattern by age (age group).

FIG. 4 is an exemplary diagram showing an operation screen displayed when the electronic apparatus of the first embodiment determines an auditory property.

FIG. 5 is an exemplary diagram to explain the relationship between a combination of attribute information and the number of hearings and auditory property patterns.

FIG. 6 is an exemplary diagram showing a functional block of an acoustic signal correction control utility program that runs on the electronic apparatus of the first embodiment.

FIG. 7 is an exemplary flowchart showing an operating procedure of the acoustic signal correction control utility program that runs on the electronic apparatus of the first embodiment.

### DETAILED DESCRIPTION

Various embodiments will be described hereinafter with reference to the accompanying drawings.

In general, according to one embodiment, an electronic apparatus includes a sound output module, a number-of-hearings input module, an auditory property determination module, and an acoustic signal correction module. The sound output module is configured to output sound in a first frequency band at different sound pressures a first number of times. The number-of-hearings input module is configured to receive a number of hearings of the output sound. The auditory property determination module is configured to determine an auditory property of a subject based on the number of hearings of the output sound received by the number-of-hearings input module. The acoustic signal correction module is configured to correct an acoustic signal based on the auditory property determined by the auditory property determination module.

### First Embodiment

First, a first embodiment will be explained.

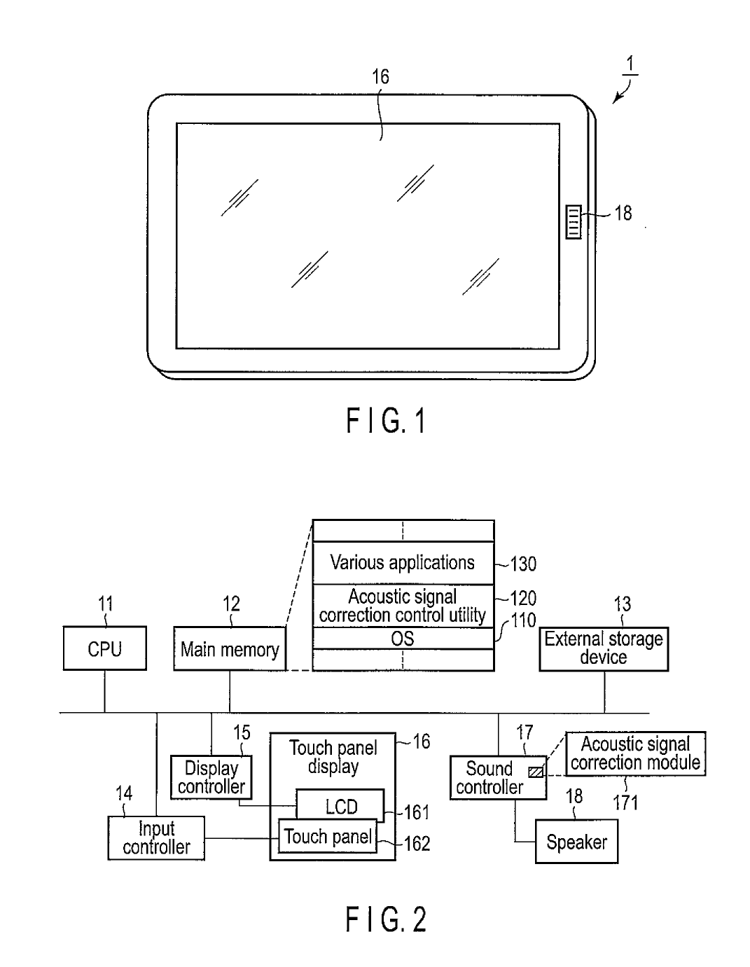

FIG. 1 is an exemplary diagram showing an external appearance of an electronic apparatus 1 according to the first embodiment. As shown in FIG. 1, the electronic apparatus 1 is implemented as, for example, a tablet personal computer (PC) that has a thin board-like housing, with a touch panel display 16 arranged on the front side of the central part of the housing. The user performs a touch operation on the touch panel display 16, thereby giving an operation instruction to the electronic apparatus 1. The electronic apparatus 1 includes the function of outputting an acoustic signal. A speaker 18 is arranged in the peripheral part of the touch panel display 16, specifically, around the front face of the housing.

FIG. 2 is an exemplary diagram showing a system configuration of the electronic apparatus 1.

As shown in FIG. 2, the electronic apparatus 1 includes a central processing unit (CPU) 11, a main memory 12, an external storage device 13, an input controller 14, a display controller, the touch panel display 16, a sound controller 17 and the speaker 18.

The CPU 11, which is a processor that controls the operation of the electronic apparatus 1, executes various programs loaded from the external storage device 13, such as a solid-state drive (SSD), into the main memory 12. The various programs executed by the CPU 11 includes an operating system (OS) 110 that supervises resource management, and an acoustic signal correction utility program 120 and various application programs 130 that run under the control of OS 110.

The input controller 14 is a controller for controlling data input by a touch operation on the touch panel display 16. A liquid-crystal display (LCD) 161 and a touch panel 162 are incorporated into the touch panel display 16. When a touch operation is performed on the touch panel display 16, the touch panel 162 outputs input information including a position on the touch panel 162 to the input controller 14. The input controller 14 stores the input information into its own register and informs the CPU 11 of this by generating an interrupt, causing the CPU 11 to read the input information stored in the register. This informs the OS 110 of the generation of an event of a touch operation on the touch panel display 16. The OS 110 notifies the generation of the event to the acoustic signal correction control utility program 120 or the various application programs 130, for example, which displays an operation screen (or window) in a position on the LCD 161 corresponding to a position on the touch panel 162 shown by input information.

The display controller 15 is a controller for controlling the display of an image on the LCD 161 incorporated in the touch panel display 16. The display controller 15 includes an accelerator that draws, in place of the CPU 11, images to be displayed by various programs.

The sound controller 17, which is a sound source device, generates an acoustic signal corresponding to audio data to be reproduced and outputs the acoustic signal to the speaker 18. The sound controller 17 includes an acoustic signal correction module 171 that corrects an acoustic signal output to the speaker 18. The acoustic signal correction control utility program 120 is a program that supervises control of the acoustic signal correction module 171. The acoustic signal correction module 171 performs the process of correcting an acoustic signal on the basis of a parameter set by the acoustic signal correction control utility program 120. The electronic apparatus 1 is configured to measure hearing acuity to set the parameter suitably by a simple and easy method. This will be explained in detail below.

While, for example, an acoustic signal is corrected by the acoustic signal correction module 171 included in the sound controller 17 composed of an integrated circuit (IC), the function of correcting an acoustic signal may be implemented as one of the various programs executed by the CPU 11. In addition, all the functions of the sound controller 17 may be implemented as one of the various programs executed by the CPU 11.

The acoustic signal correction module 171 has several patterns of average auditory property (auditory property data) in advance. The aforementioned parameter is for specifying any one of the auditory property patterns. The acoustic signal correction control program 120 makes measurements to acquire the minimum information necessary to select the optimum one from the auditory property patters prepared in advance (held by the acoustic signal correction module 171) instead of detailed hearing acuity measurements generally made until now.

Specifically, 4-kHz pure tones at several sound pressures are prepared. The user (subject) is caused to listen to the tones. It is tested up to what dB of sound pressure the user can hear, depending on how many tones the user can listen to. With the test, the user's hearing acuity at 4-kHz is obtained. According to the 4-kHz hearing acuity, which of the prepared auditory property patterns is suitable is determined.

For example, 4-kHz sounds at 5, 10, 15, and 20 dB are prepared. The user is caused to listen to these sounds in determining auditory property. When the number of sounds the user could listen to was two, since it is conceivable that the user could listen to the sounds in descending order, it can be thought that the user could listen to sounds at 20 and 15 dB and could not at 10 and 5 dB. That is, the user's hearing acuity at 4 kHz is estimated to be about 15 dB.

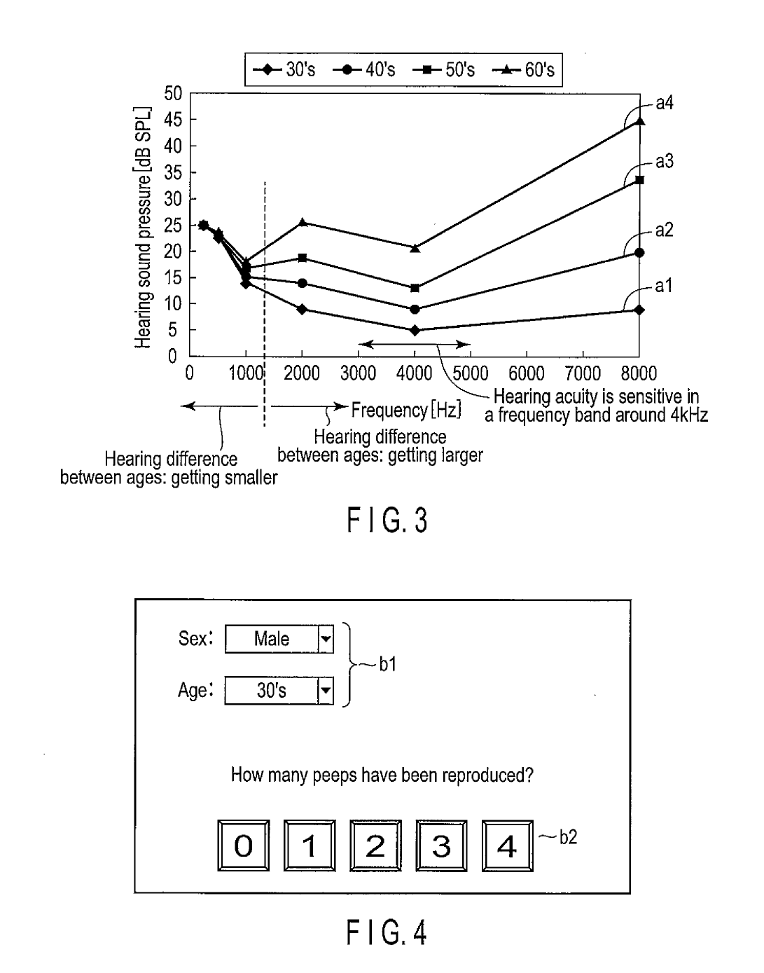

FIG. 3 is an exemplary graph showing an auditory property pattern by age (age group). Specifically, FIG. 3 shows a graph obtained by measuring a certain number of subjects in auditory the hearing acuity and averaging the measured values by age. In FIG. 3, a1 shows an average auditory property pattern for subjects in their thirties, a2 shows an average auditory property pattern for subjects in their forties, a3 shows an average auditory property pattern for subjects in their fifties, and a4 shows an average auditory property pattern for subjects in their sixties. From FIG. 3, the auditory property pattern where the 4-kHz hearing acuity is closest to 15 dB is the average auditory property pattern for subjects in their fifties. Therefore, this auditory property pattern should be used to make hearing correction.

Here, the reason why hearing acuity has only to be measured at 4 kHz will be explained.

In FIG. 3, there is not much difference between hearing people and older people at 1000 Hz or below. Therefore, when it is determined which of the auditory property patterns is suitable, hearing acuity has only to be measured at 2000, 4000, and 8000 Hz.

Next, for example, although it is not best to correct the hearing acuity of an average person in his or her sixties on the basis of the auditory property of a person in his or her fifties or forties, an adverse effect on the average person is considered to be little because the person can hear more easily than when the hearing acuity is not corrected. In contrast, when the hearing acuity of an average person in his or her thirties is corrected on the basis of the auditory property of a person in his or her sixties, the person will hear sound of excessive middle and high frequencies. This is considered to have an adverse effect on the average person because the person will hear a rattling sound, a high-pitched sound, an offensive sound, or the like.

Generally, human hearing is sensitive to around 4000 Hz. If how sensitive hearing is at 4000 Hz is known, such an auditory property as prevents the aforementioned adverse effect can be selected. Therefore, when the best one is selected from the prepared auditory properties, it is effective to measure hearing acuity in a frequency band where human hearing is as sensitive as possible, preferably at 4000 kHz.

FIG. 4 is an exemplary diagram showing an operation screen displayed on the touch panel display when the acoustic signal correction control utility program 120 determines auditory properties.

As shown in FIG. 4, on the operation screen, firstly, there are provided fields b1 for inputting attribute information, including “sex” and “age.” Secondly, there is provided a field b2 for inputting the number of times the user could listen to sound. On the operation screen, the user first inputs attribute information.

After attribute information has been input to fields b1, the acoustic signal correction control utility program 120 outputs 4-kHz sounds at, for example, 5, 10, 15, and 20 dB from the speaker 18. The order in which the sound (test sound) is output may be in ascending order of sound pressure or in descending order of sound pressure. Moreover, the order may be at random.

After the output of the test sound is completed, the acoustic signal correction control utility program 120 inputs how many times the subject could hear the test sound. On the basis of the attribute information inputted by the user and the number of times the user could hear the sound, the acoustic signal correction control utility program 120 selects the best one of the auditory property patterns held by the acoustic signal correction module 171 and sets a parameter corresponding to the selected auditory property pattern in the acoustic signal correction module 171.

The relationship between a combination of attribute information, including sex and age, and the number of hearings of test sound and auditory property patterns will be explained with reference to FIG. 5.

In FIG. 5, set A (c1) is a group of subjects whose number of hearings of test sound is the same. Since four sounds differing in sound pressure are output, five groups whose number of hearings ranges from 0 to 4 are formed in set A (c1).

Even when the number of hearings of test sound is the same, subjects differ in sex or age, their auditory property patterns might differ. Sets a1 (c11), a2 (c12), . . . , an (c1n) are groups formed by branching, on the basis of attribute information, a group of subjects whose number of hearings of test sound is the same. Therefore, the acoustic signal correction module 171 does not hold an average hearing acuity characteristic pattern for each set A (c1) whose number of hearings of test sound and holds an average auditory property pattern for each of sets a1, a2, . . . , an (c11, c12, . . . , c1n) which are branched from set A (c1) and (whose number of hearings of test sound is the same and) whose attribute information is the same.

For example, an auditory property pattern held by the acoustic signal correction module 171 is determined so that the degree of correction to each frequency component of an acoustic signal may increase as an age input as attribute information is greater.

This realizes the maintenance of the accuracy of hearing correction in simplifying the measurement of hearing acuity. Even when average auditory property patterns are prepared for each set A whose number of hearings of test sound is the same, taking no account of attribute information, including sex and age, the accuracy of hearing correction can be maintained with a high probability.

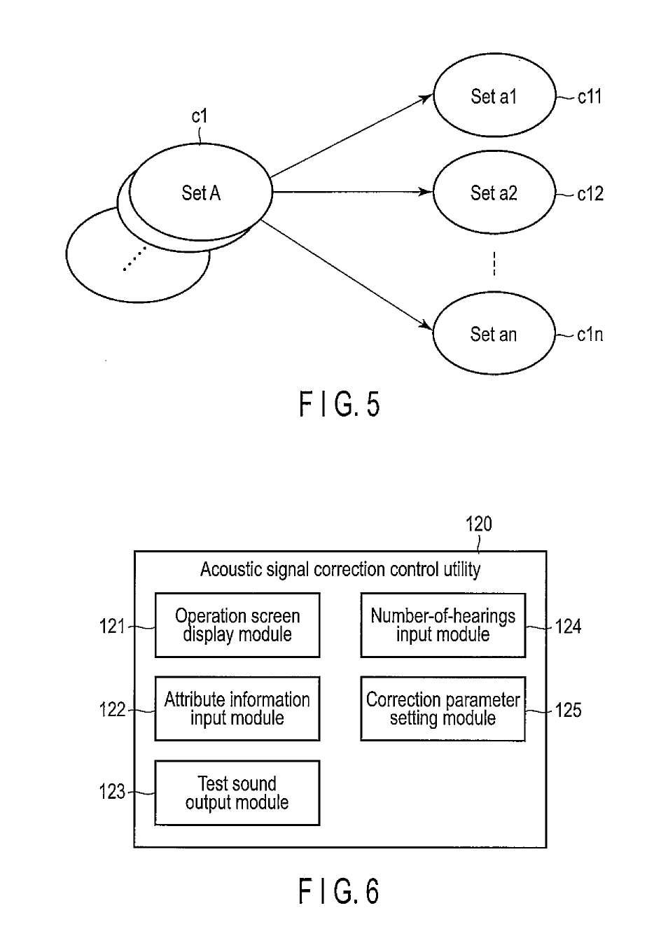

FIG. 6 is an exemplary diagram showing a functional block of the acoustic signal correction control utility program 120.

As shown in FIG. 6, the acoustic signal correction control utility program 120 includes an operation screen display module 121, an attribute information input module 122, a test sound output module 123, a number-of-hearings input module 124, a correction parameter setting module 125.

The operation screen display module 121 is a module that displays an operation screen of FIG. 4 on the touch panel display 16. The attribute information input module 122 is a module that receives attribute information input to fields b1 on the operation screen displayed on the touch panel display 16 by the operation screen display module 121. The test sound output module 123 is a module that outputs 4-kHz sound at, for example, 5, 10, 15, and 20 dB from the speaker 18.

The number-of-hearings input module 124 is a module that receives the number of hearings input to field b2 on the operation screen displayed on the touch panel display 16 by the operation screen display module 121 after the test sound is output from the speaker 18 by the test sound output module 123. The correction parameter setting module 125 is a module that selects the best one from the auditory property patterns previously prepared by the acoustic signal correction module 171 on the basis of attribute information received by the attribute information input module 122 and the number of hearings received by the number-of-hearings input module 124 and sets a parameter corresponding to the selected auditory property pattern in the acoustic signal correction module 171.

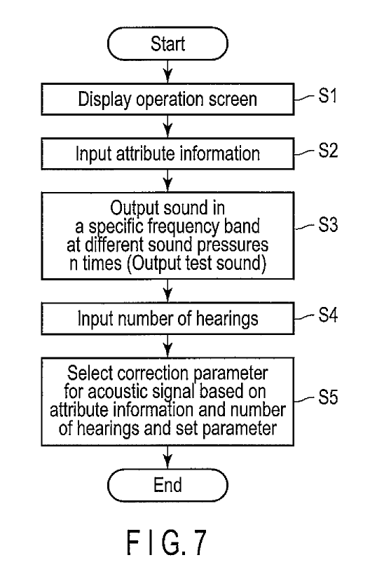

The operating procedure of the acoustic signal correction control utility program 120 configured as described above will be explained with reference to a flowchart in FIG. 7.

The acoustic signal correction control utility program 120 first displays the operation screen of FIG. 4 on the touch panel display 16 (block S1). Next, the acoustic signal correction control utility program 120 receives attribute information input to fields b1 on the operation screen displayed on the touch panel display 16 (block S2).

After having received attribute information, the acoustic signal correction control utility program 120 outputs 4-kHz sound at, for example, 5, 10, 15, and 20 dB from the speaker 18 (block S3). After having output the test sounds, the acoustic signal correction control utility program 120 receives the number of hearings input to field b2 on the operation screen displayed on the touch panel display 16 (block S4).

Then, the acoustic signal correction control utility program 120 selects the best one from the auditory property patterns previously prepared by the acoustic signal correction module 171 on the basis of the received attribute information and the number of hearings and sets a parameter corresponding to the selected auditory property pattern in the acoustic signal correction module 171 (block S5).

As a result, from this time on, the acoustic signal correction module 171 will make the optimum correction to an acoustic signal output from the speaker 18 so that the correction may be most suitable for the user (subject).

As described above, the electronic apparatus 1 of the first embodiment realizes the simplification of the measurement of hearing acuity, while maintaining the accuracy of hearing correction.

### Second Embodiment

Next, a second embodiment will be explained.

In the first embodiment, an example of causing a subject to listen to 4000-Hz test sound has been explained. It is generally said that human hearing is sensitive in a range from about 3000 Hz to about 5000 Hz. Therefore, in the second embodiment, the acoustic signal correction control utility program 120 causes a subject to listen to sound in a frequency range from about 3000 Hz to about 5000 Hz. In this case, the user may be caused to listen to sounds of 3000, 4000, and 5000 Hz one after another at different sound pressures.

As in the first embodiment, the question “How many peeps have been reproduced?” has been displayed on the operation screen of FIG. 4, it has been assumed that “peep” pure tone would be output at all the sound pressures. In contrast, in the second embodiment that causes the subject to listen to sounds in a frequency band from about 3000 Hz to about 5000 Hz, the subject may be caused to listen to not only pure sound but also sound composed of frequency components ranging from 3000 to 5000 Hz.

That is, using sound in a frequency band from about 3000 Hz to about 5000 Hz as test sound in place of only 4000-Hz sound, the electronic apparatus 1 of the second embodiment optimizes the obtained number of hearings, thereby realizing the increase of the accuracy of hearing correction.

### Third Embodiment

Next, a third embodiment will be explained.

In the third embodiment, a statistical relationship between attribute information, including sex and age, and accurate hearing acuity is measured in advance and the subject is caused to input attribute information instead of the measurement of hearing acuity, thereby determining the optimum auditory property pattern indirectly. When an auditory property pattern for an older person has been selected, a hearing-corrected acoustic signal tends to become louder in sound than the original acoustic signal. However, even if sound is a little offensive to the ear, some person may like louder sound better than soft sound, depending on individual taste. Therefore, as attribute information to be input, a liking for a high volume or for a comfortable volume may be prepared in addition to sex and age.

That is, the electronic apparatus 1 of the third embodiment realizes a remarkable reduction in the work the user is forced to do in determining an auditory property for hearing correction (because the user need not measure hearing acuity and has only to input attribute information).

Since the operation control process in each of the first to third embodiments can be realized in software (programs), the software is installed into an ordinary computer via a computer-readable storage medium that has stored the software. Then, the computer executes the software, enabling the same effects as those of each of the first to third embodiments to be realized easily.

The various modules of the systems described herein can be implemented as software applications, hardware and/or software modules, or components on one or more computers, such as servers. While the various modules are illustrated separately, they may share some or all of the same underlying logic or code.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An electronic apparatus comprising:
a sound output module configured to output sound in a first frequency band at different sound pressures a first number of times;
a number-of-hearings input module configured to receive a number of hearings of the output sound;
an auditory property determination module configured to determine an auditory property of a subject based on the number of hearings of the output sound received by the number-of-hearings input module; and
an acoustic signal correction module configured to correct an acoustic signal based on the auditory property determined by the auditory property determination module.

2. The device of claim 1, further comprising an attribute information input module configured to receive attribute information on the subject,
wherein the auditory property determination module is further configured to determine the auditory property based on the number of hearings of the output sound received by the number-of-hearings input module and the attribute information received by the attribute information input module.

3. The device of claim 2, wherein:
the acoustic signal correction module is further configured to hold a plurality of auditory property data; and
the auditory property determination module is further configured to select an auditory property data from the plurality of auditory property data held by the acoustic signal correction module, the selected auditory property data corresponding to a combination of the number of hearings of the output sound received by the number-of-hearings input module and the attribute information received by the attribute information input module.

4. The device of claim 1, wherein the first frequency band comprises 4000 Hz.

5. The device of claim 1, wherein the first frequency band ranges from 3000 to 5000 Hz.

6. The device of claim 1, wherein the sound pressure of the sound is 5, 10, 15, or 20 dB.

7. The device of claim 2, wherein the attribute information comprises sex.

8. The device of claim 2, wherein the attribute information comprises age group.

9. The device of claim 3, wherein:
the attribute information comprises age group; and
the plurality of auditory property data held by the acoustic signal correction module are determined so that a degree of correction to each frequency component of the acoustic signal increases as an age group received as the attribute information is greater.

10. An electronic apparatus comprising:
an attribute information input module configured to receive attribute information on a subject;
an auditory property determination module configured to determine an auditory property of the subject based on the attribute information received by the attribute information input module; and
an acoustic signal correction module configured to correct an acoustic signal based on the auditory property determined by the auditory property determination module.

11. The device of claim 10, wherein:
the acoustic signal correction module is further configured to hold a plurality of auditory property data, and
the auditory property determination module is further configured to select an auditory property data from the plurality of auditory property data held by the acoustic signal correction module, the selected auditory property data corresponding to the attribute information received by the attribute information input module.

12. The device of claim 10, wherein the attribute information comprises sex.

13. The device of claim 10, wherein the attribute information comprises age group.

14. The device of claim 11, wherein:
the attribute information comprises age group; and
the plurality of auditory property data held by the acoustic signal correction module are determined so that a degree of correction to each frequency component of the acoustic signal increases as an age group input as the attribute information is greater.

15. A method for an electronic apparatus that outputs an acoustic signal to correct the acoustic signal, the method comprising:
outputting sound in a first frequency band at different sound pressures a first number of times;
receiving a number of hearings of the output sound;
determining an auditory property of a subject based on the received number of hearings of the output sound; and
correcting an acoustic signal based on the determined auditory property.

16. The method of claim 15, further comprising receiving attribute information on the subject,
wherein the determining the auditory property of the subject comprises determining the auditory property based on the received number of hearings of the output sound and the received attribute information.

17. A non-transitory computer-readable storage medium having stored thereon a computer program executable by a computer that outputs an acoustic signal, the computer program controlling the computer to function as:
a sound output module configured to output sound in a first frequency band at different sound pressures a first number of times;
a number-of-hearings input modules configured to receive a number of hearings of output sound;
an auditory property determination module configured to determine an auditory property of a subject based on the number of hearings of the output sound received by the number-of-hearings input module; and
an acoustic signal correction module configured to correct an acoustic signal based on the auditory property determined by the auditory property determination module.

18. The medium of claim 17, wherein the computer program further controls the computer to function as an attribute information input module configured to receive attribute information on the subject,
wherein the auditory property determination module is further configured to determine the auditory property based on the number of hearings of output sound received by the number-of-hearings input module and the attribute information received by the attribute information input module.

19. The medium of claim 18, wherein:
the acoustic signal correction module is configured to hold a plurality of auditory property data, and
the auditory property determination module is configured to select an auditory property data from the plurality of auditory property data held by the signal correction module, the selected auditory property data corresponding to a combination of the number of hearings of the output sound received by the number-of-hearings input module and the attribute information received by the attribute information input module.
